(19) United States
(12) Patent Application Publication
(10) Pub. No.: US 2004/0113286 A1
(43) Pub. Date: Jun. 17, 2004

(54) Image sensor package without a frame layer

(76) Inventors: Jackson Hsieh, Hsinchu Hsien (TW); Jichen Wu, Hsinchu Hsien (TW); Bruce Chen, Hsinchu Hsien (TW); Eric Chang, Hsinchu Hsien (TW)

Correspondence Address: PRO-TECHTOR INTERNATIONAL, 20775 Norada Court, Saratoga, CA, 95070-3018, US

(21) Appl. No.: 10/321,915

(22) Filed: Dec. 16, 2002

(51) Int. Cl. H05K 1/09

(52) U.S. Cl. 257/787

(57) ABSTRACT

An image sensor package without a frame layer. The image sensor package includes a substrate, a photosensitive chip, a transparent layer, a plurality of wires, and a glue layer. The substrate has an upper surface formed with signal input terminals, and a lower surface formed with signal output terminals electrically connected to a printed circuit board. The photosensitive chip includes a photosensitive region and bonding pads formed on a periphery of the photosensitive region. The transparent layer is adhered to the photosensitive region by an adhesive. Each of the wires has a first terminal and a second terminal. The first terminals are electrically connected to the bonding pads, respectively, and the second terminals are electrically connected to the signal input terminals, respectively, so as to electrically connect the photosensitive chip to the substrate. The glue layer covers over the substrate for sealing the plurality of wires.

### BACKGROUND OF THE INVENTION

1. Field of the Invention

The invention relates to an image sensor package, and more particularly to an image sensor package in which a transparent layer is directly coated on a chip without using a frame layer.

2. Description of the Related Art

Referring to FIG. 1, a conventional image sensor package includes a substrate 10, a frame layer 18, a photosensitive chip 26, a plurality of wires 28 and a transparent layer 34. The substrate 10 has a first surface 12 formed with signal input terminals 15, and a second surface 14 formed with signal output terminals 16. The frame layer 18 has an upper surface 20 and a lower surface 22, which is adhered onto the first surface 12 of the substrate 10 to form a cavity 24 together with the substrate 10. The photosensitive chip 26 is arranged within the cavity 24 and is mounted to the first surface 12 of the substrate 10. Each of the wires 28 has a first terminal 30 and a second terminal 32. The first terminals 30 are electrically connected to the photosensitive chip 26 and the second terminals 32 are electrically connected to the signal input terminals 15 of the substrate 10, respectively. The transparent layer 34 is placed on the upper surface 20 of the frame layer 18.

When the photosensitive chip 26 has a greater size and the wires 28 have to be bonded and electrically connected to the signal input terminals 15 of the substrate 10, the processes cannot be performed conveniently or even the wire-bonding process cannot be performed. In this case, the size of the substrate 10 has to be enlarged to enlarge the wire-bonding space between the frame layer 18 and the photosensitive chip 26. Consequently, the overall package volume for the photosensitive chip may be enlarged, thereby causing inconvenience in usage.

### SUMMARY OF THE INVENTION

An object of the invention is to provide an image sensor package, which may be easily manufactured.

Another object of the invention is to provide a low-cost image sensor package.

Still another object of the invention is to provide an image sensor package, in which photosensitive chips with various specifications may be individually packaged without enlarging the package volume. Thus, various image sensor packages with the same volume and different specifications may be obtained.

Yet still another object of the invention is to provide an image sensor package capable of effectively reducing the package volume thereof.

To achieve the above-mentioned objects, the invention provides an image sensor package for being mounted on a printed circuit board. The image sensor package includes a substrate, a photosensitive chip, a transparent layer, a plurality of wires, and a glue layer. The substrate has an upper surface formed with a plurality of signal input terminals, and a lower surface formed with a plurality of signal output terminals, which is electrically connected to the printed circuit board. The photosensitive chip includes a photosensitive region and a plurality of bonding pads formed on a periphery of the photosensitive region. The transparent layer is adhered to the photosensitive region of the photosensitive chip by an adhesive. Each of the wires has a first terminal and a second terminal. The first terminals are electrically connected to the bonding pads of the photosensitive chip, respectively, and the second terminals are electrically connected to the signal input terminals of the substrate, respectively, so as to electrically connect the photosensitive chip to the substrate. The glue layer covers over the substrate for sealing the plurality of wires.

### BRIEF DESCRIPTION OF THE DRAWINGS

FIG. 1 is a schematic illustration showing a conventional image sensor package.

FIG. 2 is a cross-sectional view showing an image sensor package of the invention.

FIG. 3 is a first schematic illustration showing the method for manufacturing the image sensor package of the invention.

FIG. 4 is a second schematic illustration showing the method for manufacturing the image sensor package of the invention.

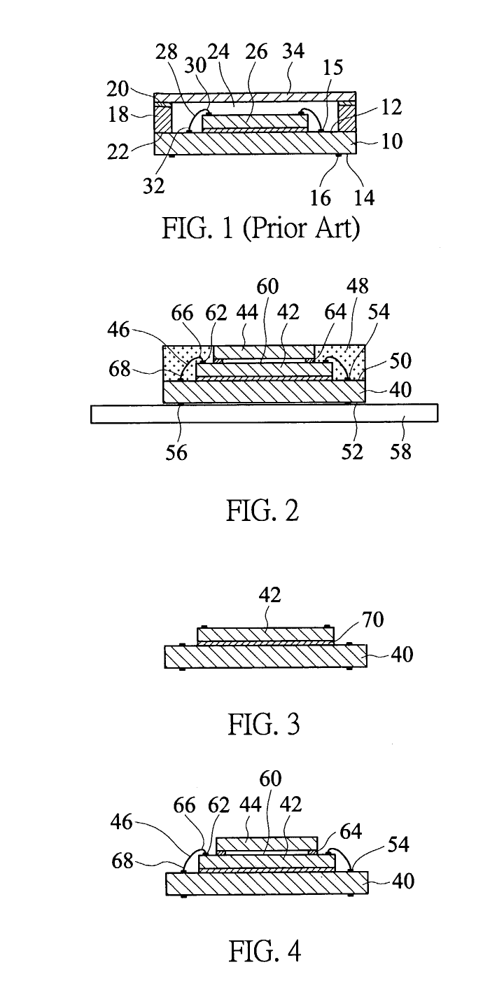

### DETAILED DESCRIPTION OF THE INVENTION

Referring to FIG. 2, an image sensor package of the invention includes a substrate 40, a photosensitive chip 42, a transparent layer 44, a plurality of wires 46 and a glue layer 48.

The substrate 40 has an upper surface 50 formed with a plurality of signal input terminals 54, and a lower surface 52 formed with a plurality of signal output terminals 56, which is electrically connected to a printed circuit board 58.

The photosensitive chip 42 includes a photosensitive region 60 and a plurality of bonding pads 62 formed at a periphery of the photosensitive region 60.

The transparent layer 44 is a piece of transparent glass adhered onto the photosensitive region 60 of the photosensitive chip 42 by an adhesive 64. The adhesive 64 is coated on a periphery of the photosensitive region 60 of the photosensitive chip 42. The photosensitive chip 42 may receive optical signals passing through the transparent layer 44. In addition, the transparent layer 44 also may be a transparent glue layer directly coated onto the photosensitive region 60 of the photosensitive chip 42 so that the photosensitive chip 42 may receive optical signals passing through the transparent glue layer.

Each of the wires 46 has a first terminal 66 and a second terminal 68. The first terminals 66 are electrically connected to the bonding pads 62 of the photosensitive chip 42, respectively. The second terminals 68 are electrically connected to the signal input terminals 54 of the substrate 40, respectively. Thus, the photosensitive chip 42 may be electrically connected to the substrate 40.

The glue layer 48 covers the substrate 40 to encapsulate, seal and protect the wires 46.

The method for manufacturing an image sensor package of the invention will be described with reference to FIGS. 3 and 4.

First, the photosensitive chip 42 is adhered to the upper surface 50 of the substrate 40 by an adhesive layer 70, as shown in FIG. 3. Furthermore, as shown in FIG. 4, the adhesive 64 is coated on the periphery of the photosensitive region 60 of the photosensitive chip 42, and then the transparent layer 44 is adhered to the photosensitive chip 42 by the adhesive 64 so that the photosensitive chip 42 may receive optical signals passing through the transparent layer 44. Moreover, the first terminals 66 of the wires 46 are electrically connected to the bonding pads 62 of the photosensitive chip 42, respectively. On the other hand, the second terminals 68 are electrically connected to the signal input terminals 54 of the substrate 40, respectively. Then, as shown in FIGS. 4 and 2, the glue layer 48 is provided to cover the upper surface 50 of the substrate 40 and to encapsulate and seal the wires 46.

The image sensor package of the invention has the following advantages.

1. No frame layer has to be provided. Thus, the manufacturing processes may be simplified and the overall package volume may be reduced. In addition, the wire-bonding process may be easily performed because no frame layer may interfere with the process.

2. Various photosensitive chips 32 having different sizes may be individually packaged on the substrates 30 having the same size. Thus, various image sensor packages with the same volume and different specifications may be obtained.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor package for being mounted on a printed circuit board, the image sensor package comprising:
a substrate having an upper surface formed with a plurality of signal input terminals, and a lower surface formed with a plurality of signal output terminals, which is electrically connected to the printed circuit board;
a photosensitive chip including a photosensitive region and a plurality of bonding pads formed on a periphery of the photosensitive region;
a transparent layer adhered to the photosensitive region of the photosensitive chip by an adhesive;
a plurality of wires, each of which having a first terminal and a second terminal, the first terminals being electrically connected to the bonding pads of the photosensitive chip, respectively, and the second terminals being electrically connected to the signal input terminals of the substrate, respectively, so as to electrically connect the photosensitive chip to the substrate; and
a glue layer covering over the substrate for sealing the plurality of wires.

2. The image sensor package according to claim 1, wherein the transparent layer is a piece of transparent glass and the adhesive is coated on the periphery of the photosensitive region of the photosensitive chip to adhere the transparent glass to the photosensitive region of the photosensitive chip.

3. The image sensor package according to claim 1, wherein the transparent layer is a transparent glue layer coated on the photosensitive region of the photosensitive chip.
